(19) United States
(12) Patent Application Publication
(10) Pub. No.: US 2024/0273265 A1
(43) Pub. Date: Aug. 15, 2024

(54) METHODS AND APPARATUS TO DESIGN AND TEST ELECTRONICS USING ARTIFICIAL INTELLIGENCE

(71) Applicant: Intel Corporation, Santa Clara, CA (US)

(72) Inventors: Souvik Kundu, Los Angeles, CA (US); Sharath Nittur Sridhar, San Diego, CA (US); Anahita Bhiwandiwalla, San Jose, CA (US)

(21) Appl. No.: 18/620,453

(22) Filed: Mar. 28, 2024

(51) Int. Cl. G06F 30/27

(52) U.S. Cl. CPC G06F 30/27

(57) ABSTRACT

Methods, apparatus, systems, and articles of manufacture design and test electronics using artificial intelligence are disclosed. An example apparatus includes programmable circuitry to instantiate: use a first trained artificial intelligence (AI)-based model to generate verification code based on an input design; execute the verification code to generate a verifiability score for the input design; and based on the verifiability score, use a second trained AI-model to adjust the input design.

### BACKGROUND

When an electronic device (e.g., a system, a chip, an integrated circuit, and/or software) is designed for one or more particular uses, the design is tested to verify that the electronic device will operate as intended. To verify a design, software (e.g., verification code) is developed to simulate, anticipate, and/or detect errors in the design. The verification code, when executed, can identify whether the design works as intended and/or if the design exhibits errors. If the output of the verification code identifies that the design is valid and/or verified, the verification of the design is complete. If the output of the verification code identifies that the design is invalid and/or not verifiable, the design may be adjusted or discarded to attempt to improve the design (e.g., before the corresponding product is sold and/or released for sale).

### BRIEF DESCRIPTION OF THE DRAWINGS

FIG. 1 is a block diagram of an example computing device for training and/or utilizing artificial intelligence-based models for generating verification code and/or increasing verifiability of electronic devices.

FIG. 2 is a block diagram of an example implementation of the model training circuitry of FIG. 1.

FIG. 3 is a block diagram of an example implementation of the design and verification circuitry of FIG. 1.

FIG. 4 is a block diagram of an example implementation of the multimodal model of FIG. 3.

FIG. 5 is a flowchart representative of example machine-readable instructions and/or operations that may be executed, instantiated, and/or performed by programmable circuitry to implement the model training circuitry of FIG. 2.

FIG. 6 is a flowchart representative of example machine-readable instructions and/or operations that may be executed, instantiated, and/or performed by programmable circuitry to implement the model training circuitry of FIG. 2.

FIG. 7 is a flowchart representative of example machine-readable instructions and/or operations that may be executed, instantiated, and/or performed by programmable circuitry to implement the design generation and verification circuitry of FIG. 3.

FIG. 8 is a flowchart representative of example machine-readable instructions and/or operations that may be executed, instantiated, and/or performed by programmable circuitry to implement the multimodal model circuitry of FIG. 4.

FIG. 9 is a block diagram of an example processor platform including programmable circuitry structured to execute, instantiate, and/or perform the computer readable instructions and/or perform the example operations of FIGS. 5-8 to implement at least one of the model training circuitry, the multimodal model circuitry, and/or the design generation and verification circuitry of FIGS. 1-4.

FIG. 10 is a block diagram of an example implementation of the programmable circuitry of FIG. 9.

FIG. 11 is a block diagram of another example implementation of the programmable circuitry of FIG. 9.

FIG. 12 is a block diagram of an example software/firmware/instructions distribution platform (e.g., one or more servers) to distribute software, instructions, and/or firmware (e.g., corresponding to the example machine-readable instructions of FIG. 9) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale.

### DETAILED DESCRIPTION

When generating and/or developing new systems (e.g., hardware systems, firmware systems, integrated circuits, field programmable gate arrays (FPGA), application specific integrated circuitry, chips, software, etc.), proper operation of the electronic devices and/or electronic systems need to be verified before being manufactured. The verification stage of development includes generating verification code (e.g., also referred to as verification script) to test the functionality of an electronic devices and/or electronic system design and/or verify that the electronic devices and/or electronic system design (e.g., testing whether the electronic devices and/or electronic system will work as intended, identifying potential errors or bugs, etc.). Execution of the verification code may identify errors and/or verify the functionality of the electronic devices and/or electronic system design. In many examples, the amount of time to generate verification code is significantly longer than the amount of time to develop a design. The success and yield of a product corresponding to the design is heavily dependent on the success of the design verification stage.

Traditionally, the generation of verification code during the verification stage is a largely manual process. Not only is the manual process of the generation of verification code slow, but, if the verifiability stage identifies issues (e.g., the design has errors or does not work as intended), the process returns to the design stage to adjust or redesign the product to remove or reduce the identified errors. After the design has been adjusted, the verification stage is redone based on the updated design. Accordingly, the amount of time to verify a design is significant due to the back-and-forth process between the design and verification stage. Additionally, the success of the verification process depends on the skills and creativity of the engineer(s) that designed the verification code. For example, if the engineer(s) or person(s) designing the verification code do not consider particular worst case scenarios, the verification code may not properly identify whether the design will work properly when implemented.

Examples disclosed herein utilize generative artificial intelligence (AI) to generate verification code for verifying product designs. As used herein, a product design is a design of any electronic system, product, device, hardware, firmware, integrated circuits, field programmable gate arrays (FPGA), application specific integrated circuitry, chips, software, etc. Generative AI-based models may include code generation modes, code auto completion models, code co-pilot models etc. that generate verification code to verify a product design. Because product designs may be generated in difference modalities (e.g., graphical representations of a system, text description of a system, flowchart representation of a system, circuit diagram of a system, etc.), examples disclosed herein train the generative AI model to generate verification code and/or script based on inputs corresponding to one or more different modalities. Additionally, examples disclosed herein may train the generative AI model using prompts obtained from a user to generate more robust and accurate verification code. A prompt is an example that can help the model develop the verification code. For example, if the product design corresponds to a 32-bit adder circuit, the prompt could be an example of a 1-bit adder circuit with an example input and an example output.

Additionally, examples disclosed herein utilize an AI-based model to update a product design based on the result of execution of generated verification code. For example, after the first AI-based model generates verification code for a product design, examples disclosed herein execute the verification code to generate a verification score. The better (e.g., the higher) the score, the fewer errors have been identified in the product design. If the verification score satisfies (e.g., is above) a threshold, the product design passes the verification stage. However, if the verification score does not satisfy (e.g., is below) the threshold, the second AI-based model of some examples adjusts the product design to increase the verifiability of the product design (e.g., to reduce the errors). The second AI-based model generates the adjusted product design based on the product design, the verification code, and/or the verifiability score. The verification code and/or updated verification code is then executed to generate an updated verifiability score for the adjusted product design and the process continues until the verifiability score of a design satisfies the threshold. Examples disclosed herein result in a more efficient, faster, and more robust verification and design stage when generated product designs.

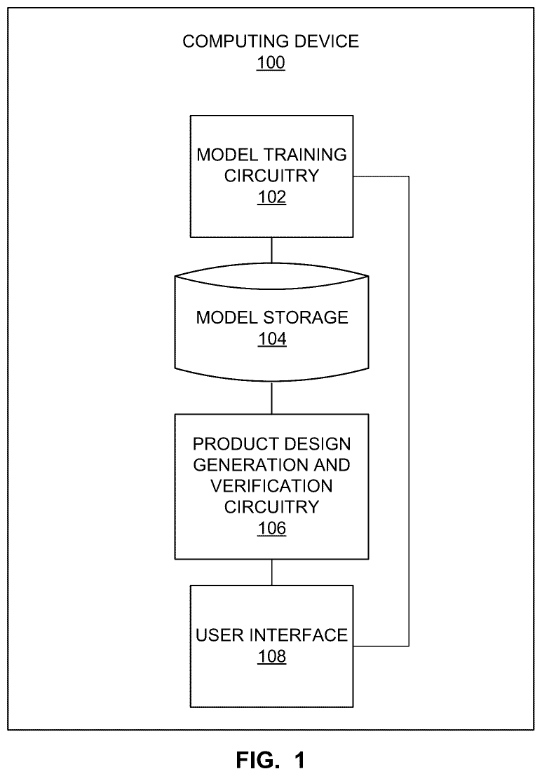

FIG. 1 is a block diagram of an example computing device 100 in which AI-based models are trained and implemented to generate verification code and update product designs. The example computing device 100 of FIG. 1 includes example model training circuitry 102, example model storage 104, example product design generation and verification circuitry 106 and an example user interface 108. The computing device 100 may be a server, a computer, a mobile device, a tablet, and/or any other device capable of training and/or implementing AI-based models. Although the computing device 100 of FIG. 1 trains and implements AI-based models, there may be two or more computing devices. For example, a first computing device may include the model training circuitry 102, the model storage 104, and the user interface 108 to train AI-based models and a second computing device may include the product design generation and verification circuitry 106 and the user interface 108 to implement a deployed AI based model trained by the first computing device.

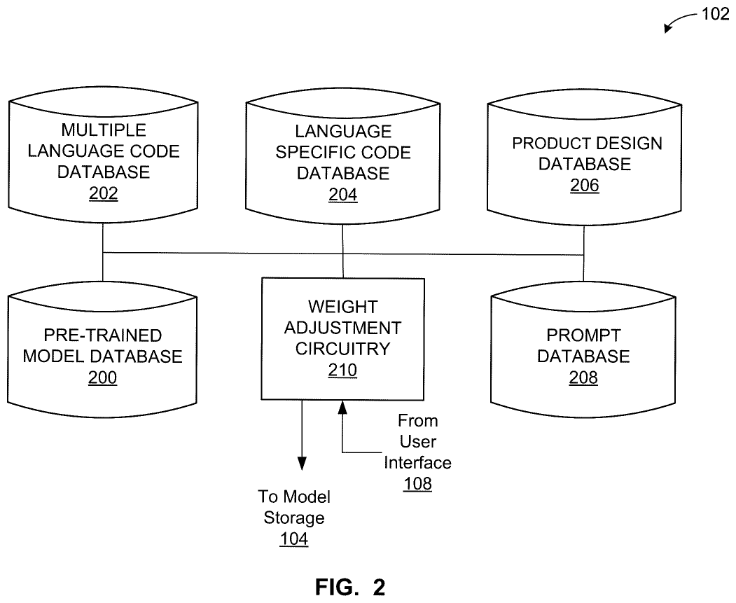

The model training circuitry 102 of FIG. 2 trains and/or fine tunes AI-based models (e.g., generative AI-based models such as large language models (LLMs)) using any combination of unsupervised, supervised, or semi-supervised learning. The model training circuitry 102 includes one or more databases with tuning data that is used to tune a pre-trained AI-based model. As further described below in conjunction with FIG. 2, the model training circuitry 102 can train and/or fine tune a verification code generation model that generates verification code for a product design based on an input product design and/or an input verification prompt. The model training circuitry 102 fine tunes a pre-trained verification code generation model to generate the verification code based on various input modalities (e.g., graphical representations of a system, text description of a system, flowchart representation of a system, circuit diagram of a system, etc.) or combinations of input modalities. The verification code, when executed, tests a product design for errors and generates a verifiability score for the design based on the testing.

Additionally, as further described below in conjunction with FIG. 2, the model training circuitry 102 of FIG. 1 can train a circuit design generation model that generates and/or adjusts product designs to increase the verifiability scores of designs with verifiability scores does not satisfy (e.g., is below) a threshold. The model training circuitry 102 stores the trained model(s) (e.g., the verification code generation model and/or the circuit design generation model) in the model storage 104. For example, if a trained model corresponds to a plurality of weight values and/or thresholds for neurons of the trained AI-based model, the model training circuitry 102 can store the plurality of weight values and/or thresholds in the model storage 104.

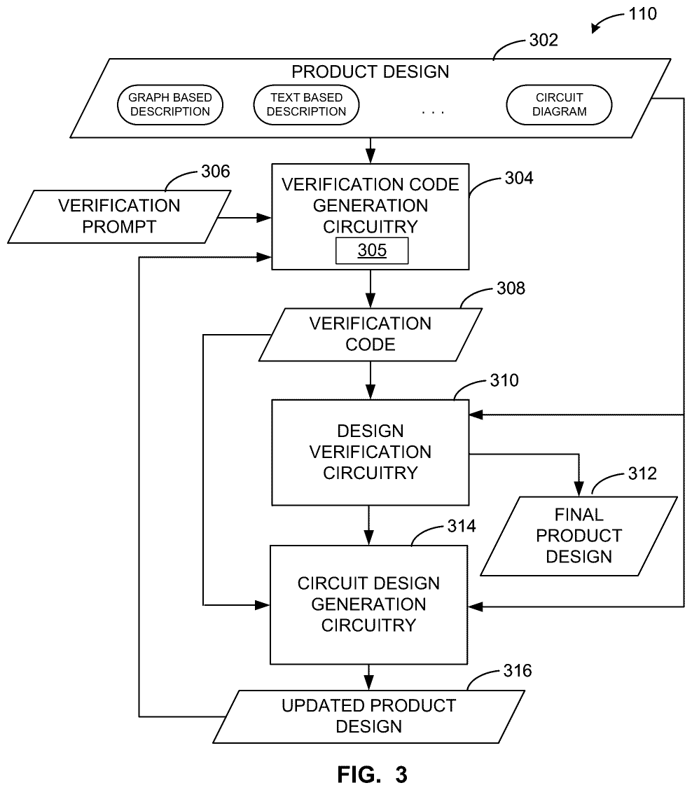

After training of the models is complete, the product design generation and verification circuitry 106 accesses the trained model data from the model storage 104 and implements the trained models to product designs for the verifiability stage. For example, the product design generation and verification circuitry 106 obtains trained verifiability code generation model data from the model storage 104 and applies a product design and/or verification prompt to the trained verifiability code generation model to generate verification code for the product design. The product design generation and verification circuitry 106 executes the verification code to verify the product design and outputs a verifiability score corresponding to whether the design works as intended. If the verification code satisfies (e.g., is above) a threshold, the product design generation and verification circuitry 106 outputs the product design as a final design and proceeds to the next stage of manufacturing. If the verification code does not satisfy (e.g., is below) the threshold, the product design generation and verification circuitry 106 applies the product design to the trained circuit design generation circuitry to adjust and/or redesign the product design to increase the verifiability score. The product design generation and verification circuitry 106 is further described below in conjunction with FIG. 3.

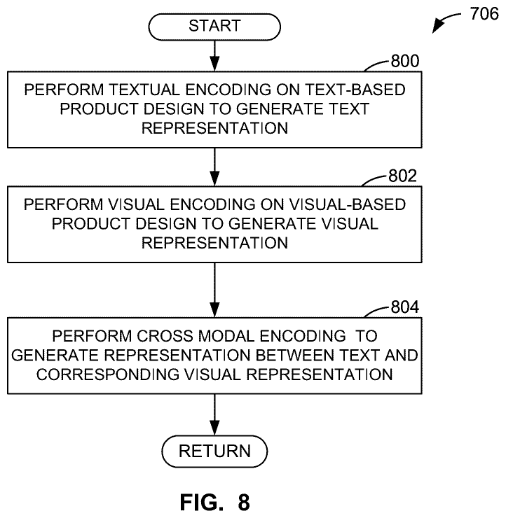

The user interface 108 of FIG. 8 interfaces with a user of the computing device 100. For example, the user interface 108 can obtain user generated product designs from the user. Additionally, the user interface 108 can provide information related to the training and/or implementation of one or more models to the user to obtain feedback. The user interface 108 can provide user feedback regarding the training and/or implementation of a model.

FIG. 2 is a block diagram of an example implementation of the model training circuitry 102 of FIG. 1. The example model training circuitry 102 of FIG. 2 includes an example pre-trained model database 200, an example multiple language code database 202, an example language specific code database 204, an example product design database 206, an example prompt database 208, and example weight adjustment circuitry 210. Although the example implementation of the model training circuitry 102 of FIG. 2 includes multiple separate databases, the model training circuitry 102 could be implemented with less databases by combining the data stored in the multiple databased into one or more databases.

The pre-trained model database 200 of FIG. 2 stores one or more pre-trained models (e.g., data that can be used to implement one or more pre-trained models). For example, the pre-trained model database 200 may store a first pre-trained verification code model to generate verification code. The pre-trained models may be a large language model (LLM). Additionally, the pre-trained model database 200 may store a second pre-trained circuit design model to generate and/or adjust product designs. The pre-trained models act as a starting point model. However, to make the pre-trained models more accurate, robust, and effective, the weight adjustment circuitry 210 fine tunes the pre-trained model(s) using information from the other databases 202-208, as further described below.

The multiple language code database 202 of FIG. 2 includes tuning data corresponding to multiple different code languages. In some examples, the tuning data is verification code that is generalized for multiple different languages (e.g., Verilog, C+, circuit description, circuit diagram, flow charts, product designs, multimodal descriptions, etc.). The verification code may be linked or labeled with specific product designs. In some examples, the tuning data includes product designs that are generalized for multiple different languages or outputs (e.g., Verilog, C+, circuit description, circuit diagram, flow charts, product designs, multimodal descriptions, etc.). The product designs may be linked or labelled with verification code, verifiability scores, and/or original product designs.

The language specific code database 204 of FIG. 2 includes tuning data corresponding to specific languages. The tuning data, when used for fine-tuning, can convert a generalized model that was fine-tuned with multiple languages to a model that corresponds to a specific language or specific one or more modalities. The tuning data can link specific languages to the generalized verification code or product design. As further described below, first fine-tuning a model to a generalized model and then fine-tuning the generalized mode to a language specific, as opposed to just fine-tuning a pre-trained model with a specific language, reduces overfitting of the input data.

The product design database 206 of FIG. 2 stores product design and/or product design adjustments to improve verifiability. The product design database can be used as inputs for fine-tuning verification code generation models or as inputs and/or outputs for fine-tuning circuit design generation models. The product designs may be linked to or labeled with corresponding verification code, corresponding verifiability scores, and/or corresponding updated product designs.

The example prompt database 208 of FIG. 2 stores prompts used for fine-tuning the verification code generation model. A prompt is an example that can help the model develop the verification code. For example, if the product design corresponds to a 32-bit adder circuit, the prompt could be an example of a 1-bit adder circuit with an example input and an example output. The prompts may be linked to or labelled with corresponding product designs and/or corresponding verification code.

The weight adjustment circuitry 210 of FIG. 2 adjusts the weights of models to fine tune (e.g., also referred to as tune) a model to a final trained model. For example, the weight adjustment circuitry 210 can fine tune a pre-trained model using the training data of the multiple language code database 202 and/or corresponding product design data from the product design database 206 to generate a generalized verification code model or a generalized product design generation model. In some examples, the weight adjustment circuitry 210 can additionally fine tune the pre-trained verification code model based on prompts from the prompt database 208. After the generalized models are generated, the weight adjustment circuitry 210 further fine tunes the generalized model(s) using the language specific (e.g., one of Verilog, C++, etc.) tuning data in the language specific code database 204. The specific language may be based on user and/or manufacturer preferences. As opposed to training the pre-trained model directly using language specific code, training the pre-trained model to a generalized model and then turning the generalized model to a language specific model reduces overfitting to a specific input type.

When tuning the generalized verification code generation model to a language specific code generation model, the weight adjustment circuitry 210 of FIG. 2 can fine tune the language specific verification code model to an instruction-based verification code model or a non-instruction-based model or task-specific verification code model based on user and/or manufacturer preferences. An instruction-based design corresponds to an input of the trained model being instructions (e.g., code, circuit description, etc.). A non-instruction-based design corresponds to the input of the trained model being non-instructions (e.g., circuit diagram, flow chart, etc.). When training to be an instruction-based verification model, the weight adjustment circuitry 210 uses language specific tuning data that is instruction based. When training to be a non-instruction-based verification model, the weight adjustment circuitry 210 uses language specific tuning data that is non-instruction based. In some examples, the weight adjustment circuitry 210 can further fine tune a non-instruction-based verification model to be a long-context-based verification model by fine-tuning the task-based verification model for long context implementations (e.g., when the product design performs various tasks or functions).

When tuning the pre-trained product design generation model to a generalized product design generation model, the weight adjustment circuitry 210 of FIG. 2 can fine obtain user feedback and use the user feedback to fine tune the product design generation model. For example, the user interface 108 may provide the user with a portion of tuning data that is used to test a product design based on the generalized product design generation model. The user can provide feedback regarding the output of the generalized system generation model via the user interface 108. The weight adjustment circuitry 210 can use the user feedback to further fine tune the generalized product design generation model.

The weight adjustment circuitry 210 of FIG. 2 performs fine-tuning by adjusting the weights, threshold, and/or any other data of a model. The weight adjustment circuitry 210 can fine tune using any fine-tuning technique(s). For example, the weight adjustment circuitry 210 can perform full fine-tuning, parameter-efficient fine-tuning, transfer learning, task-specific fine-tuning, multi-task learning, sequential fine-tuning, etc.

FIG. 3 is a block diagram of an example implementation of the product design generation and verification circuitry 106 of FIG. 1. The product design generation and verification circuitry 106 of FIG. 3 includes an example product design 302, example verification code generation circuitry 304, example multimodal encoder circuitry 305, an example verification prompt 306, an example verification code 308, example design verification circuitry 310, an example final product design 312, example circuit design generation circuitry 314, and an example updated product design 316.

The product design 302 of FIG. 2 is a design of a new system (e.g., an integrated circuit, an ASIC, etc.) to perform one or more operations.

The product design 302 may be created by a user (e.g., obtained via the user interface 108 of FIG. 1) and/or may be created by another system (e.g., an AI-based model). The product design 302 may be described in one or more different modalities. For example, the product design 302 may be one or more of a graph-based description, a text-based description, a circuit diagram, etc. The product design 302 describes how a design is intended to operate after being manufactured. The product design 302 is input into the verification code generation circuitry 304.

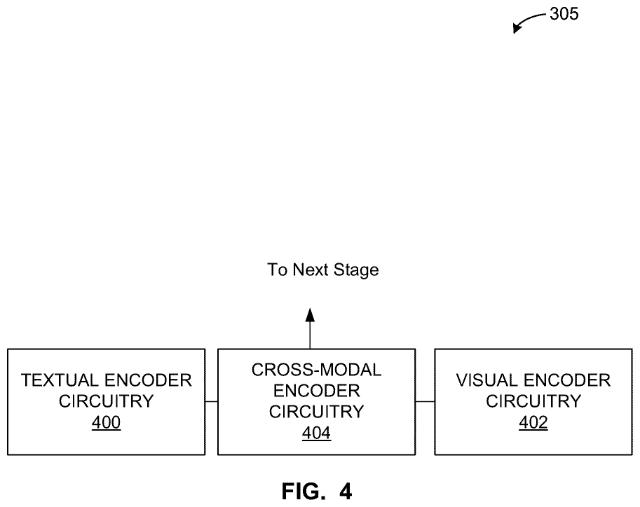

The verification code generation circuitry 304 of FIG. 3 implements the verification code generation model trained by the model training circuitry 102 of FIGS. 1-2. For example, the verification code generation circuitry 304 can obtain the AI-based model data (e.g., the weights, thresholds, structure, etc. of the trained verification code generation circuitry) from the model storage 104 to implement the trained verification code generation model. The verification code generation circuitry 304 obtains the product design 302 and the verification prompt 306 and generates output the verification code 308 based on the product design 302 and/or verification prompt 306. If the product design 302 is described in two or more different modalities (e.g., text description and circuit description), the multimodal encoder circuitry 405 combines information from the two or more different modalities into a single representation of the input product design, as further described below in conjunction with FIG. 4. As described above, the verification prompt 306 is an example that can help the model develop the verification code. For example, the verification prompt 306 may be an example input value and output value. The output value may be an expected output value of the product design when the example input value is applied to the product design. Additionally, the verification code 308 is code or script that, when executed, verifies the functionality of the product design 302. For example, the verification code can test the product design with various values and/or configurations to ensure that the product design 302 operates as intended. The verification code 308 of FIG. 3 outputs a verifiability score for the product design 302. A higher verifiability score corresponds to finding a smaller number of errors for the product design 302. A lower verifiability score corresponds to finding a larger number of errors for the product design 302. The verification code generation circuitry 304 outputs the verification code 308 to the design verification circuitry 310.

The design verification circuitry 310 of FIG. 3 executes the verification code 308 for the product design 302 to generate a verifiability score of the product design 302. As described above, the less errors that occur when executing the verification code 308, the higher the verifiability score of the product design 302. Additionally, the design verification circuitry 310 compares the output verifiability score to a threshold verifiability score. If the design verification circuitry 310 determines that the output verifiability score satisfies (e.g., is above) the threshold verifiability score, the design verification circuitry 310 outputs the product design as the final product design 312. The final product design 312 can be moved into the next stage of manufacturing. If the design verification circuitry 310 determines that the output verifiability score does not satisfy (e.g., is below) the threshold verifiability score, the design verification circuitry 310 outputs the verification score to the circuit design generation circuitry 314, to trigger the circuit design generation circuitry 314 to update or rewrite the product design 302.

The circuit design generation circuitry 314 of FIG. 3 implements the circuit design generation model trained by the model training circuitry 102 of FIGS. 1-2. For example, the circuit design generation circuitry 314 can obtain the AI-based model data (e.g., the weights, thresholds, structure, etc. of the trained verification code generation circuitry) from the model storage 104 to implement the trained verification code generation model. The circuit design generation circuitry 314 obtains the product design 302, the verification code 308, and/or the result of the design verification circuitry 310 as inputs. The circuit design generation circuitry 314 uses the inputs in the trained circuit design generation model to generate output an updated product design 316 that attempts to improve the verifiability of the product design and maintains the initial functionality of the original product design 302. The circuit design generation circuitry 314 outputs the updated product design 316 to the verification code generation circuitry 304 to generate new verifiability code for testing the updated product design.

FIG. 4 is a block diagram of an example implementation of the multimodal encoder circuitry 305 of FIG. 3. The example multimodal encoder circuitry 305 of FIG. 4 includes example textual encoder circuitry 400, example visual encoder circuitry 402, and example cross-modal encoder circuitry 404.

The textual encoder circuitry 400 of FIG. 4 performs textual encoding on text-based product designs. For example, the textual encoder circuitry 300 can extract features from the input textual data and convert the input data into a common representation or format understood by the model. In some examples, the textual encoder circuitry 300 can transform text into word embeddings where similar words are presented as numerical vectors.

The visual encoder circuitry 402 of FIG. 4 performs visual encoding on the visual-based product design. For example, the visual encoder circuitry 402 can extract features from the input visual data and convert the input data into a common representation. In some examples, the visual encoder circuitry 402 may use convolution neural networks to encode images.

The example cross-modal encoder circuitry 404 of FIG. 4 performs cross modal encoding (also referred to as multimodal fusion) to generate representation between the text and corresponding visual representation. The cross-modal encoder circuitry 404 combines the information from the different modalities into a single representation. For example, the cross-modal encoder circuitry 404 may perform a weighted sum of the modality features outputs of the textual encoder circuitry 300 and the visual encoder circuitry 402.

While an example manner of implementing the model training circuitry 102 and the product design generation and verification circuitry 106 of FIG. 1 is illustrated in FIGS. 2-3, one or more of the elements, processes, and/or devices illustrated in FIG. 2 may be combined, divided, re-arranged, omitted, eliminated, and/or implemented in any other way. Further, the weight adjustment circuitry 210, the verification code generation circuitry 304, the multimodal encoder circuitry 305, the design verification circuitry 310, the circuit design generation circuitry 314, the textual encoder circuitry 400, the visual encoder circuitry 402, the cross-modal encoder circuitry 404, and/or, more generally, the model training circuitry 102 and the product design generation and verification circuitry 106 of FIGS. 2-3, may be implemented by hardware alone or by hardware in combination with software and/or firmware. Thus, for example, any of the weight adjustment circuitry 210, the verification code generation circuitry 304, the multimodal encoder circuitry 305, the design verification circuitry 310, the circuit design generation circuitry 314, the textual encoder circuitry 400, the visual encoder circuitry 402, the cross-modal encoder circuitry 404, and/or, more generally, the model training circuitry 102 and the product design generation and verification circuitry 106 of FIGS. 2-3, could be implemented by programmable circuitry in combination with machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the model training circuitry 102 and the product design generation and verification circuitry 106 of FIGS. 2-3 may include one or more elements, processes, and/or devices in addition to, or instead of, those illustrated in FIGS. 1-4, and/or may include more than one of any or all of the illustrated elements, processes, and devices.

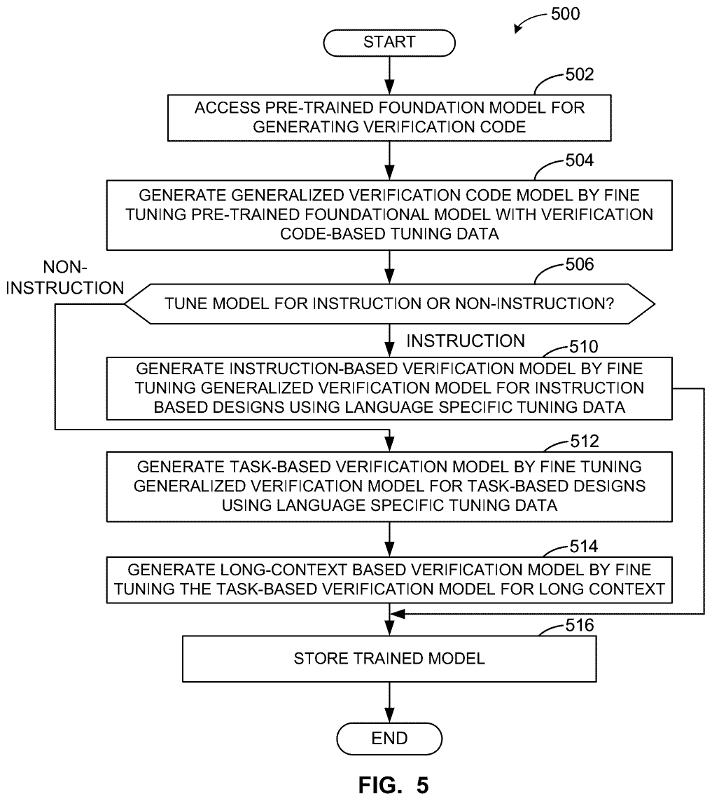

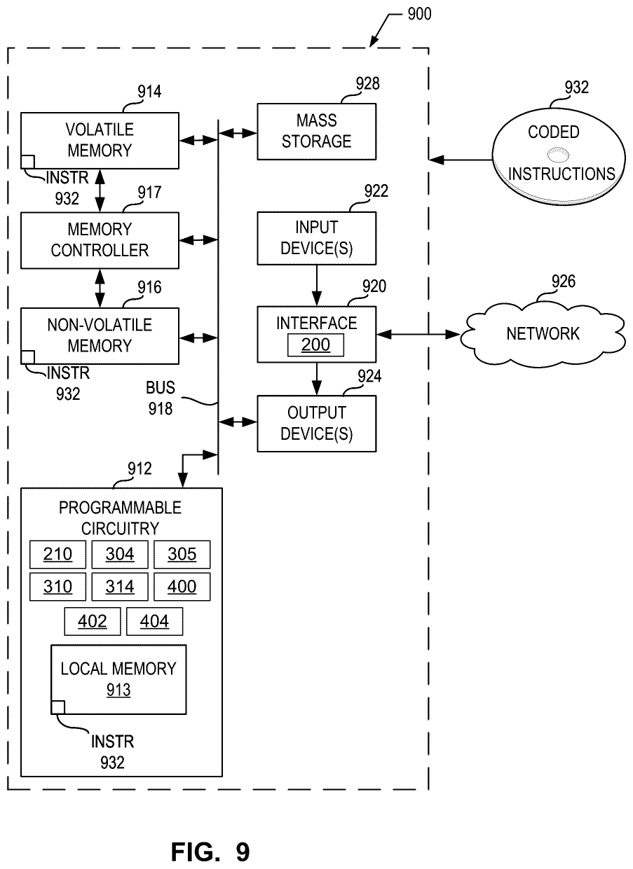

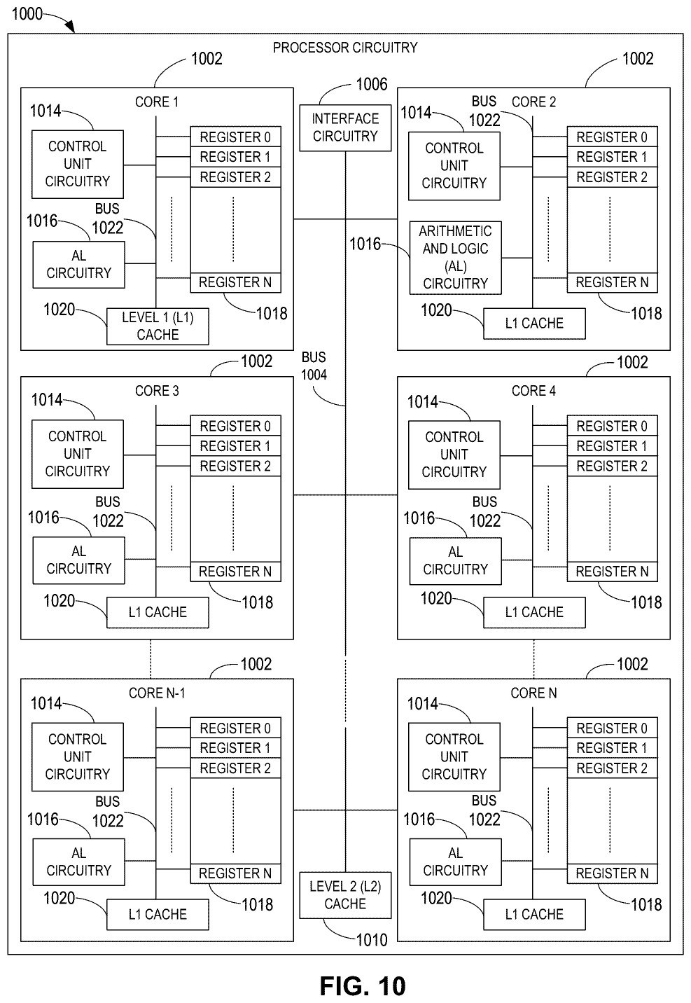

Flowchart(s) representative of example machine-readable instructions, which may be executed by programmable circuitry to implement and/or instantiate the model training circuitry 102 and the product design generation and verification circuitry 106 of FIGS. 2-3 and/or representative of example operations which may be performed by programmable circuitry to implement and/or instantiate the model training circuitry 102 and the product design generation and verification circuitry 106 of FIGS. 2-3, is shown in FIGS. 5-8. The machine-readable instructions may be one or more executable programs or portion(s) of one or more executable programs for execution by programmable circuitry such as the programmable circuitry 912 shown in the example processor platform 900 discussed below in connection with FIG. 9 and/or may be one or more function(s) or portion(s) of functions to be performed by the example programmable circuitry (e.g., an FPGA) discussed below in connection with FIGS. 10 and/or 11. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 5-8, many other methods of implementing the model training circuitry 102 and the product design generation and verification circuitry 106 of FIGS. 2-3 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions and/or the corresponding program(s) can be executed in whole or in part. Thus, machine-readable, computer-readable, and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C #, Perl, Python, JavaScript, HyperText Markup Language (HTML), Structured Query Language (SQL), Swift, Go Lang, etc.

As mentioned above, the example operations of FIG. 3 may be implemented using executable instructions (e.g., computer readable and/or machine-readable instructions) stored on one or more non-transitory computer readable and/or machine-readable media. As used herein, the terms non-transitory computer readable medium, non-transitory computer readable storage medium, non-transitory machine-readable medium, and/or non-transitory machine-readable storage medium are expressly defined to include any type of computer readable storage device and/or storage disk and to exclude propagating signals and to exclude transmission media. Examples of such non-transitory computer readable medium, non-transitory computer readable storage medium, non-transitory machine-readable medium, and/or non-transitory machine-readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine-readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C.

As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or operations, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or operations, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

Descriptors “first,” “second,” “third,” etc. are used herein when identifying multiple elements or components which may be referred to separately. Unless otherwise specified or understood based on their context of use, such descriptors are not intended to impute any meaning of priority or ordering in time but merely as labels for referring to multiple elements or components separately for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for ease of referencing multiple elements or components.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

FIG. 5 is a flowchart representative of example machine-readable instructions and/or example operations 500 that may be executed, instantiated, and/or performed by programmable circuitry(ies) to train a verification code generation model. For example, the example operations 500 may be executed, instantiated, and/or performed by the model training circuitry 102 of FIG. 2. The example machine-readable instructions and/or the example operations 500 of FIG. 5 begin at block 502, at which the weight adjustment circuitry 210 accesses a pre-trained foundation model for generating verification code from the pre-trained model database 200. The pre-trained model database 200 stores pre-trained models that act as a starting point for generating a fully trained verification code generation model. In some examples, the weight adjustment circuitry 210 can train a model from scratch using training data stored in one or more of the databases 200-208 of FIG. 2.

At block 504, the weight adjustment circuitry 210 generates a generalized verification model by fine-tuning the pre-trained foundational model with verification code-based tuning data. For example, the weight adjustment circuitry 210 can access multiple language code data from the multiple language code database 202 and/or prompts corresponding to the product designs from the prompt database 208. The weight adjustment circuitry 210 uses the accessed data to adjust the weights of the pre-trained model to generate the generalize verification code model.

At block 506 of FIG. 5, the weight adjustment circuitry 210 determines if the generalized verification code model is to be tuned for an instruction-based design or a non-instruction-based design. An instruction-based design corresponds to the input of the trained model being instructions (e.g., code, circuit description, etc.). A non-instruction-based design corresponds to an input of the trained model being non-instructions (e.g., circuit diagram, flow chart, etc.). The decision to select an instruction-based model or a non-instruction-based model may be based on user and/or manufacturer preferences. If the weight adjustment circuitry 210 determines that the model is to be tuned for instructions (block 506: INSTRUCTION), the weight adjustment circuitry 210 generates an instruction-based verification model by fine-tuning generalized verification model for instruction-based designs using language specific product design data that corresponds to instruction-based models from the language specific code database 204 (block 510). The trained instruction-based verification model outputs verification code based on language specific instruction-based input data.

If the weight adjustment circuitry 210 determines that the model is to be tuned for instructions (block 506: NON-INSTRUCTION), the weight adjustment circuitry 210 generates a non-instruction-based verification model by fine-tuning generalized verification model for non-instruction-based designs using language specific product design data that corresponds to non-instruction-based models from the language specific code database 204 (block 512). The trained instruction-based verification model outputs verification code based on language specific non-instruction-based input data. At block 514, the weight adjustment circuitry 210 generates the long-context-based verification model by fine-tuning the task-based verification model for long context. The weight adjustment circuitry 210 fine tunes any of the models using any fine-tuning technique (e.g., feature extraction, full fine-tuning, etc.). At block 516, the weight adjustment circuitry 210 stores the trained model int the example model storage 104. For example, the weight adjustment circuitry 210 may store data corresponding to the structure of the trained model (e.g., number or neurons, number of layers, etc.) and the value(s) of the weights and/or threshold needed to implement the trained model.

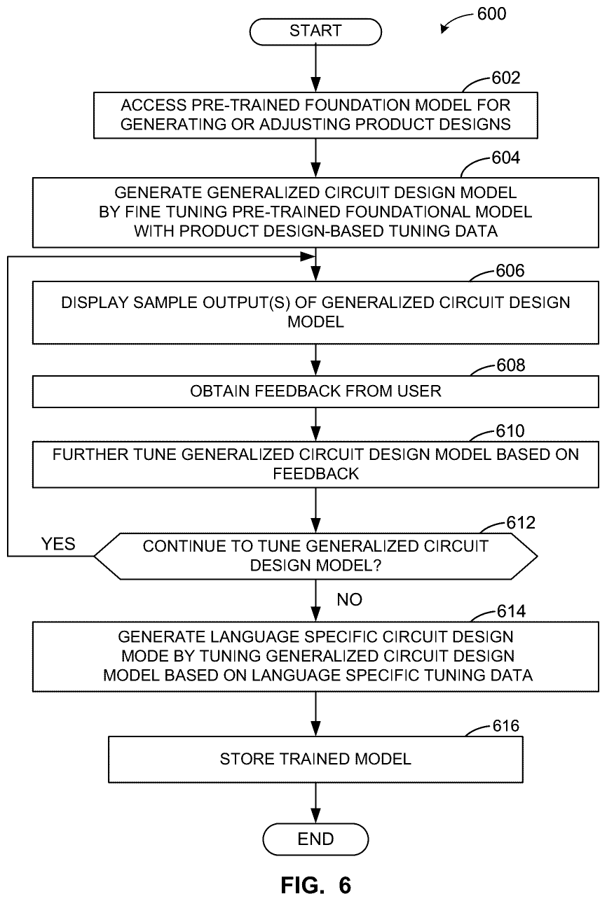

FIG. 6 is a flowchart representative of example machine-readable instructions and/or example operations 600 that may be executed, instantiated, and/or performed by programmable circuitry(ies) to train a circuit design generation model. For example, the example operations 600 may be executed, instantiated, and/or performed by the model training circuitry 102 of FIG. 2. The example machine-readable instructions and/or the example operations 600 of FIG. 6 begin at block 602, at which the weight adjustment circuitry 210 accesses a pre-trained foundation model for generating product designs from the pre-trained model database 200. The pre-trained model database 200 stores pre-trained models that act as a starting point for generating a fully trained product design generation model. In some examples, the weight adjustment circuitry 210 can train a model from scratch using tuning data stored in one or more of the databases 200-208 of FIG. 2.

At block 604, the weight adjustment circuitry 210 generates a generalized circuit design model by fine-tuning a pre-trained foundational model with system-design based tuning data. For example, the weight adjustment circuitry 210 can access data from the multiple language code database 202 and/or corresponding data from the product design database 206 to fine tune the pre-trained foundational model. At block 606, the weight adjustment circuitry 210 displays sample output(s) of the generalized circuit design model. For example, the weight adjustment circuitry 210 can apply a sample product design as an input to the generalized circuit design model to generate a sample output. The weight adjustment circuitry 210 outputs the sample result to the user interface 108 to provide the sample result and/or input sample product design to a user for feedback. The output may include a prompt that questions the user as to the sample output.

At block 608, the weight adjustment circuitry 210 obtains feedback from the user via the user interface 108. At block 610, the example weight adjustment circuitry 210 further tunes the generalized circuit design model based on the user feedback. At block 612, the example weight adjustment circuitry 210 determines whether to continue to tune the generalized circuit design model. In some examples, the weight adjustment circuitry 210 determines whether to continue tuning based on the user feedback and/or based on the accuracy of the generalized circuit design model. For example, the weight adjustment circuitry 210 can utilize a portion of the data from the product design database 206 to test the accuracy of the generalized circuity design model. If the weight adjustment circuitry 210 determines that the generalized circuit design model is to continue to be tuned (block 612: YES), control returns to block 606. If the weight adjustment circuitry 210 determines that the generalized circuit design mode is not to continue to be tuned (block 612: NO), control continues to block 614.

At block 614, the weight adjustment circuitry 210 generates a language specific circuit design model by tuning the generalize circuit design based on the language specific tuning data. For example, the weight adjustment circuitry 210 utilizes data from the language specific code database 204 to further tune the generalized circuit design model. At block 616, the example weight adjustment circuitry 210 stores the trained model in the example model storage 104. For example, the weight adjustment circuitry 210 may store data corresponding to the structure of the trained model (e.g., number or neurons, number of layers, etc.) and the value(s) of the weights and/or thresholds needed to implement the trained model.

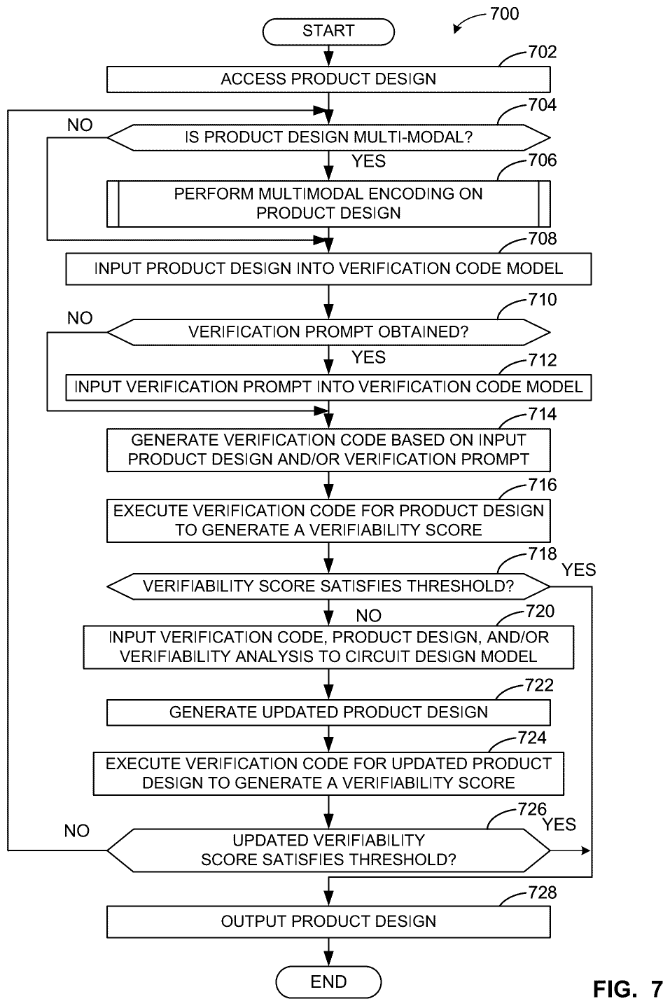

FIG. 7 is a flowchart representative of example machine-readable instructions and/or example operations 700 that may be executed, instantiated, and/or performed by programmable circuitry(ies) to verify and/or adjust a product design. For example, the example operations 700 may be executed, instantiated, and/or performed by the product design generation and verification circuitry 106 of FIG. 3. The example machine-readable instructions and/or the example operations 700 of FIG. 7 begin at block 702, at which the verification code generation circuitry 304 accesses the product design 302. As described above, the product design 302 may be one or more of a graph-based description, a text-based description, a circuit diagram, etc. In some examples, the verification code generation circuitry 304 accesses the product design from the user interface 108, a network interface, and/or storage.

At block 702, the multimodal encoder circuitry 405 determines if the description of the product design is multi-modal. For example, if the product design 302 includes some graph-based description and some text-based description, the multimodal encoder circuitry 405 determines that the product design 302 is multi-modal. If the multimodal encoder circuitry 405 determines that the product design 302 is not multi-modal (block 704: NO), control continues to block 708. If the multimodal encoder circuitry 405 determines that the product design is multi-modal (block 706: YES), the multimodal encoder circuitry 405 performs multimodal encoding on the product design 302 (block 706), as further described below in conjunction with the flowchart of FIG. 8. As described above, the cross-modal encoding combines the multiple modalities into a single modality.

At block 708, the verification code generation circuitry 304 inputs the product design into a trained verification code model. The verification code generation circuitry 304 may access information related to a trained model from the example model storage 104 of FIG. 1 and implement the trained model based on the accessed information. At block 710, the example verification code generation circuitry 304 determines if the verification prompt 306 has been obtained. The verification prompt 306 is an example that can help the model develop the verification code. The verification code generation circuitry 304 may obtain a verification prompt 306 via the user interface 108, a network interface, and/or from storage. If the verification code generation circuitry 304 determines that the verification prompt 306 has not been obtained (block 710: NO), control continues to block 714. If the verification code generation circuitry 304 determines that the verification prompt 306 has been obtained (block 710: YES), the verification code generation circuitry 304 inputs the verification prompt 306 into the trained verification code model (block 712).

At block 714, the example verification code generation circuitry 304 generates the verification code 308 based on the input product design 302 and/or the verification prompt 306 using the trained verification code generation model. As described above, the verification code 308 is code and/or script that, when executed, generates a verifiability score based on the product design 302. The verifiability score corresponds to the number of errors or bugs associated with the product design 302. At block 716, the example design verification circuitry 310 executes the verification code 308 to generate a verifiability score of the product design 302. At block 718, the example design verification circuitry 310 determines if the verifiability score satisfies (e.g., is above) a threshold. The threshold may be based on user and/or manufacturer preferences. If the design verification circuitry 310 determines that the verifiability score does not satisfy the threshold (block 718: NO), control continues to block 720, as further described below. If the design verification circuitry 310 determines that the verifiability score satisfies the threshold (block 718: YES), the design verification circuitry 310 outputs the tested product design as the final product design 312 (block 282) and the instructions end.

At block 720, the example circuit design generation circuitry 314 inputs the verification code, the product design, and/or the verifiability analysis to a trained circuit design model. At block 722, the example circuit design generation circuitry 314 generates the updated product design 316 based on the input(s). At block 724, the design verification circuitry 310 executes the verification code for the updated product design 316 to generate an updated verifiability score for the updated product design 316. At block 726, the example design verification circuitry 310 determines if the updated verifiability score satisfies (e.g., is above) the threshold. If the design verification circuitry 310 determines that the updated verifiability score does not satisfy the threshold (block 726: NO), control returns to block 704 to perform an additional iteration to attempt to increase the verifiability of the product design. If the design verification circuitry 310 determines that the updated verifiability score satisfies the threshold (block 726: YES), the design verification circuitry 310 outputs the final product design.

FIG. 8 is a flowchart representative of example machine-readable instructions and/or example operations 706 that may be executed, instantiated, and/or performed by programmable circuitry(ies) to perform multimodal encoding on the product design, as described above in conjunction with block 706 of FIG. 7. For example, the example operations 706 may be executed, instantiated, and/or performed by the multimodal encoder circuitry 305 of FIG. 4. The example machine-readable instructions and/or the example operations 706 of FIG. 8 begin at block 800, at which the textual encoder circuitry 300 performs textual encoding on the text-based product design. For example, the textual encoder circuitry 300 extracts features from the input textual data and converts the input data into a common representation (e.g., by transforming input data into feature vectors).

At block 802, the visual encoder circuitry 402 performs visual encoding on the visual-based product design. For example, the visual encoder circuitry 402 extracts features from the input visual data and converts the input data into a common representation. At block 804, the example cross-modal encoder circuitry 404 performs cross modal encoding to generate representation between the text and corresponding visual representation. For example, the cross-modal encoder circuitry 404 combines the information from the different modalities into a single representation (e.g., using a weighted sum of the modality features).

FIG. 9 is a block diagram of an example programmable circuitry platform 900 structured to execute and/or instantiate the example machine-readable instructions and/or the example operations of FIGS. 5-8 to implement the model training circuitry 102 and/or the product design generation and verification circuitry 106 of FIGS. 1-4. The programmable circuitry platform 900 can be, for example, a server, a personal computer, a workstation, a self-learning machine (e.g., a neural network), or any other type of computing and/or electronic device.

The programmable circuitry platform 900 of the illustrated example includes programmable circuitry 912. The programmable circuitry 912 of the illustrated example is hardware. For example, the programmable circuitry 912 can be implemented by one or more integrated circuits, logic circuits, FPGAs, microprocessors, CPUs, GPUs, DSPs, and/or microcontrollers from any desired family or manufacturer. The programmable circuitry 912 may be implemented by one or more semiconductor based (e.g., silicon based) devices. In this example, the weight adjustment circuitry 210, the verification code generation circuitry 304, the multimodal encoder circuitry 305, the design verification circuitry 310, the circuit design generation circuitry 314, the textual encoder circuitry 400, the visual encoder circuitry 402, and the cross-modal encoder circuitry 404 of FIGS. 2-4.

The programmable circuitry 912 of the illustrated example includes a local memory 913 (e.g., a cache, registers, etc.). The programmable circuitry 912 of the illustrated example is in communication with main memory 914, 916, which includes a volatile memory 914 and a non-volatile memory 916, by a bus 918. The volatile memory 914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 916 may be implemented by flash memory and/or any other desired type of memory device. Access to the main memory 914, 916 of the illustrated example is controlled by a memory controller 917. In some examples, the memory controller 917 may be implemented by one or more integrated circuits, logic circuits, microcontrollers from any desired family or manufacturer, or any other type of circuitry to manage the flow of data going to and from the main memory 914, 916. Any one or more of the main memory 914, 916 or the local memory 913 can implement the model storage 104 and/or the databases 200, 202, 204, 206, 208 of FIGS. 1 and/or 2.

The programmable circuitry platform 900 of the illustrated example also includes interface circuitry 920. The interface circuitry 920 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 922 are connected to the interface circuitry 920. The input device(s) 922 permit(s) a user (e.g., a human user, a machine user, etc.) to enter data and/or commands into the programmable circuitry 912. The input device(s) 922 can be implemented by, for example, a keyboard, a button, a mouse, and/or a touchscreen.

One or more output devices 924 are also connected to the interface circuitry 920 of the illustrated example. The output device(s) 924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), and/or speaker. The interface circuitry 920 of the illustrated example, thus, typically includes a graphics driver card, a graphics driver chip, and/or graphics processor circuitry such as a GPU.

The interface circuitry 920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 926. The communication can be by, for example, an Ethernet connection, a digital subscriber line (DSL) connection, a telephone line connection, a coaxial cable system, an optical fiber connection, a satellite system, a beyond-line-of-sight wireless system, a line-of-sight wireless system, a cellular telephone system, an optical connection, etc.

The programmable circuitry platform 900 of the illustrated example also includes one or more mass storage discs or devices 928 to store firmware, software, and/or data. Examples of such mass storage discs or devices 928 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine-readable instructions 932, which may be implemented by the machine-readable instructions of FIGS. 5-8, may be stored in the mass storage device 928, in the volatile memory 914, in the non-volatile memory 916, and/or on at least one non-transitory computer readable storage medium such as a CD or DVD which may be removable.

FIG. 10 is a block diagram of an example implementation of the programmable circuitry 912 of FIG. 9. In this example, the programmable circuitry 912 of FIG. 9 is implemented by a microprocessor 1000. For example, the microprocessor 1000 may be a general-purpose microprocessor (e.g., general-purpose microprocessor circuitry). The microprocessor 1000 executes some or all of the machine-readable instructions of the flowcharts of FIG. 3 to effectively instantiate the circuitry of FIGS. 1 and/or 2 as logic circuits to perform operations corresponding to those machine-readable instructions. In some such examples, the circuitry of FIGS. 10 and/or 11 is instantiated by the hardware circuits of the microprocessor 1000 in combination with the machine-readable instructions. For example, the microprocessor 1000 may be implemented by multi-core hardware circuitry such as a CPU, a DSP, a GPU, an XPU, etc. Although it may include any number of example cores 1002 (e.g., 1 core), the microprocessor 1000 of this example is a multi-core semiconductor device including N cores. The cores 1002 of the microprocessor 1000 may operate independently or may cooperate to execute machine-readable instructions. For example, machine code corresponding to a firmware program, an embedded software program, or a software program may be executed by one of the cores 1002 or may be executed by multiple ones of the cores 1002 at the same or different times. In some examples, the machine code corresponding to the firmware program, the embedded software program, or the software program is split into threads and executed in parallel by two or more of the cores 1002. The software program may correspond to a portion or all of the machine-readable instructions and/or operations represented by the flowchart of FIG. 3.

The cores 1002 may communicate by a first example bus 1004. In some examples, the first bus 1004 may be implemented by a communication bus to effectuate communication associated with one(s) of the cores 1002. For example, the first bus 1004 may be implemented by at least one of an Inter-Integrated Circuit (I2C) bus, a Serial Peripheral Interface (SPI) bus, a PCI bus, or a PCIe bus. Additionally or alternatively, the first bus 1004 may be implemented by any other type of computing or electrical bus. The cores 1002 may obtain data, instructions, and/or signals from one or more external devices by example interface circuitry 1006. The cores 1002 may output data, instructions, and/or signals to the one or more external devices by the interface circuitry 1006. Although the cores 1002 of this example include example local memory 1020 (e.g., Level 1 (L1) cache that may be split into an L1 data cache and an L1 instruction cache), the microprocessor 1000 also includes example shared memory 1010 that may be shared by the cores (e.g., Level 2 (L2 cache)) for high-speed access to data and/or instructions. However, in some examples the L2 cache is connected to each core 1002 and the shared memory 1010 is implemented by level 3 (L3) cache for high-speed access to data and/or instructions. Data and/or instructions may be transferred (e.g., shared) by writing to and/or reading from the shared memory 1010. The local memory 1020 of each of the cores 1002 and the shared memory 1010 may be part of a hierarchy of storage devices including multiple levels of cache memory and the main memory (e.g., the main memory 914, 916 of FIG. 9). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1002 may be referred to as a CPU, DSP, GPU, etc., or any other type of hardware circuitry. Each core 1002 includes control unit circuitry 1014, arithmetic and logic (AL) circuitry (sometimes referred to as an ALU) 1016, a plurality of registers 1018, the local memory 1020, and a second example bus 1022. Other structures may be present. For example, each core 1002 may include vector unit circuitry, single instruction multiple data (SIMD) unit circuitry, load/store unit (LSU) circuitry, branch/jump unit circuitry, floating-point unit (FPU) circuitry, etc. The control unit circuitry 1014 includes semiconductor-based circuits structured to control (e.g., coordinate) data movement within the corresponding core 1002. The AL circuitry 1016 includes semiconductor-based circuits structured to perform one or more mathematic and/or logic operations on the data within the corresponding core 1002. The AL circuitry 1016 of some examples performs integer based operations. In other examples, the AL circuitry 1016 also performs floating-point operations. In yet other examples, the AL circuitry 1016 may include first AL circuitry that performs integer-based operations and second AL circuitry that performs floating-point operations. In some examples, the AL circuitry 1016 may be referred to as an Arithmetic Logic Unit (ALU).

The registers 1018 are semiconductor-based structures to store data and/or instructions such as results of one or more of the operations performed by the AL circuitry 1016 of the corresponding core 1002. For example, the registers 1018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1018 may be arranged in a bank as shown in FIG. 10. Alternatively, the registers 1018 may be organized in any other arrangement, format, or structure, such as by being distributed throughout the core 1002 to shorten access time. The second bus 1022 may be implemented by at least one of an I2C bus, a SPI bus, a PCI bus, or a PCIe bus.

Each core 1002 and/or, more generally, the microprocessor 1000 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1000 is a semiconductor device fabricated to include many transistors interconnected to implement the structures described above in one or more integrated circuits (ICs) contained in one or more packages.

The microprocessor 1000 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1000, in the same chip package as the microprocessor 1000 and/or in one or more separate packages from the microprocessor 1000.

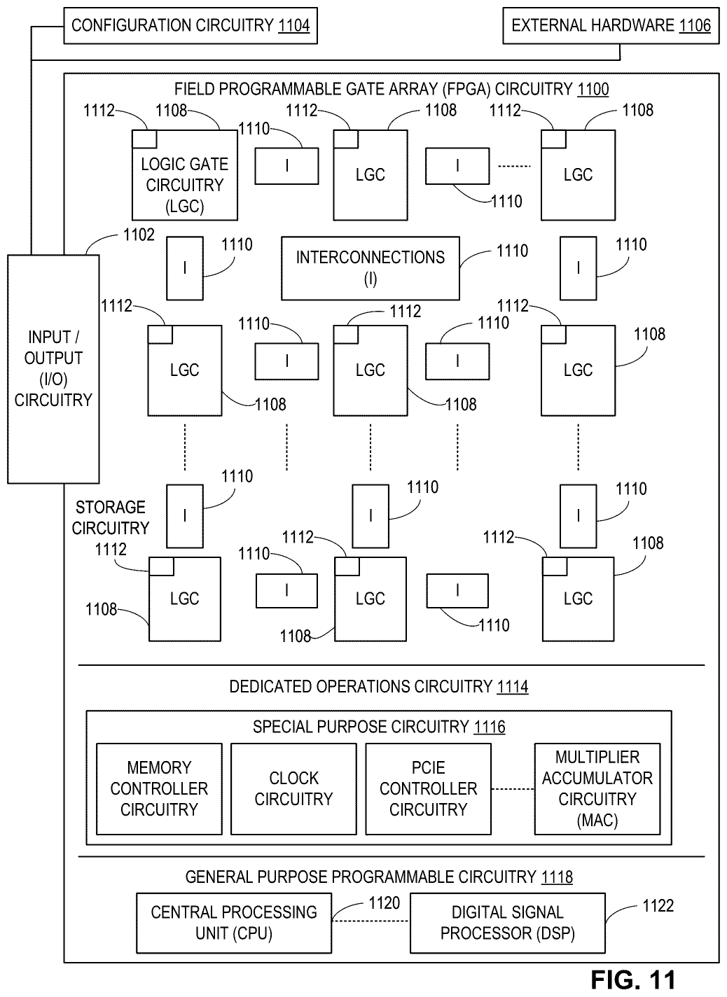

FIG. 11 is a block diagram of another example implementation of the programmable circuitry 912 of FIG. 9. In this example, the programmable circuitry 912 is implemented by FPGA circuitry 1100. For example, the FPGA circuitry 1100 may be implemented by an FPGA. The FPGA circuitry 1100 can be used, for example, to perform operations that could otherwise be performed by the example microprocessor 1000 of FIG. 10 executing corresponding machine-readable instructions. However, once configured, the FPGA circuitry 1100 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 1000 of FIG. 10 described above (which is a general purpose device that may be programmed to execute some or all of the machine-readable instructions represented by the flowchart(s) of FIG. 3 but whose interconnections and logic circuitry are fixed once fabricated), the FPGA circuitry 1100 of the example of FIG. 11 includes interconnections and logic circuitry that may be configured, structured, programmed, and/or interconnected in different ways after fabrication to instantiate, for example, some or all of the operations/functions corresponding to the machine-readable instructions represented by the flowchart(s) of FIG. 3. In particular, the FPGA circuitry 1100 may be thought of as an array of logic gates, interconnections, and switches. The switches can be programmed to change how the logic gates are interconnected by the interconnections, effectively forming one or more dedicated logic circuits (unless and until the FPGA circuitry 1100 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIG. 3. As such, the FPGA circuitry 1100 may be configured and/or structured to effectively instantiate some or all of the operations/functions corresponding to the machine-readable instructions of the flowchart(s) of FIG. 3 as dedicated logic circuits to perform the operations/functions corresponding to those software instructions in a dedicated manner analogous to an ASIC. Therefore, the FPGA circuitry 1100 may perform the operations/functions corresponding to the some or all of the machine-readable instructions of FIG. 3 faster than the general-purpose microprocessor can execute the same.

In the example of FIG. 11, the FPGA circuitry 1100 is configured and/or structured in response to being programmed (and/or reprogrammed one or more times) based on a binary file. In some examples, the binary file may be compiled and/or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1100 of FIG. 11 may access and/or load the binary file to cause the FPGA circuitry 1100 of FIG. 11 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1100 of FIG. 11 to cause configuration and/or structuring of the FPGA circuitry 1100 of FIG. 11, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1100 of FIG. 11 may access and/or load the binary file to cause the FPGA circuitry 1100 of FIG. 11 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1100 of FIG. 11 to cause configuration and/or structuring of the FPGA circuitry 1100 of FIG. 11, or portion(s) thereof.

The FPGA circuitry 1100 of FIG. 11, includes example input/output (I/O) circuitry 1102 to obtain and/or output data to/from example configuration circuitry 1104 and/or external hardware 1106. For example, the configuration circuitry 1104 may be implemented by interface circuitry that may obtain a binary file, which may be implemented by a bit stream, data, and/or machine-readable instructions, to configure the FPGA circuitry 1100, or portion(s) thereof. In some such examples, the configuration circuitry 1104 may obtain the binary file from a user, a machine (e.g., hardware circuitry (e.g., programmable or dedicated circuitry) that may implement an Artificial

Intelligence/Machine Learning (AI/ML) model to generate the binary file), etc., and/or any combination(s) thereof). In some examples, the external hardware 1106 may be implemented by external hardware circuitry. For example, the external hardware 1106 may be implemented by the microprocessor 1000 of FIG. 10.

The FPGA circuitry 1100 also includes an array of example logic gate circuitry 1108, a plurality of example configurable interconnections 1110, and example storage circuitry 1112. The logic gate circuitry 1108 and the configurable interconnections 1110 are configurable to instantiate one or more operations/functions that may correspond to at least some of the machine-readable instructions of FIG. 3 and/or other desired operations. The logic gate circuitry 1108 shown in FIG. 11 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1108 to enable configuration of the electrical structures and/or the logic gates to form circuits to perform desired operations/functions. The logic gate circuitry 1108 may include other electrical structures such as look-up tables (LUTs), registers (e.g., flip-flops or latches), multiplexers, etc.

The configurable interconnections 1110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1108 to program desired logic circuits.

The storage circuitry 1112 of the illustrated example is structured to store result(s) of the one or more of the operations performed by corresponding logic gates. The storage circuitry 1112 may be implemented by registers or the like. In the illustrated example, the storage circuitry 1112 is distributed amongst the logic gate circuitry 1108 to facilitate access and increase execution speed.

The example FPGA circuitry 1100 of FIG. 11 also includes example dedicated operations circuitry 1114. In this example, the dedicated operations circuitry 1114 includes special purpose circuitry 1116 that may be invoked to implement commonly used functions to avoid the need to program those functions in the field. Examples of such special purpose circuitry 1116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1100 may also include example general purpose programmable circuitry 1118 such as an example CPU 1120 and/or an example DSP 1122. Other general purpose programmable circuitry 1118 may additionally or alternatively be present such as a GPU, an XPU, etc., that can be programmed to perform other operations.

Although FIGS. 10 and 11 illustrate two example implementations of the programmable circuitry 912 of FIG. 9, many other approaches are contemplated. For example, FPGA circuitry may include an on-board CPU, such as one or more of the example CPU 1120 of FIG. 10. Therefore, the programmable circuitry 912 of FIG. 9 may additionally be implemented by combining at least the example microprocessor 1000 of FIG. 10 and the example FPGA circuitry 1100 of FIG. 11. In some such hybrid examples, one or more cores 1002 of FIG. 10 may execute a first portion of the machine-readable instructions represented by the flowchart(s) of FIG. 3 to perform first operation(s)/function(s), the FPGA circuitry 1100 of FIG. 11 may be configured and/or structured to perform second operation(s)/function(s) corresponding to a second portion of the machine-readable instructions represented by the flowcharts of FIG. 3, and/or an ASIC may be configured and/or structured to perform third operation(s)/function(s) corresponding to a third portion of the machine-readable instructions represented by the flowcharts of FIG. 3.

It should be understood that some or all of the circuitry of FIGS. 10 and/or 11 may, thus, be instantiated at the same or different times. For example, the same and/or different portion(s) of the microprocessor 1000 of FIG. 10 may be programmed to execute portion(s) of machine-readable instructions at the same and/or different times. In some examples, same and/or different portion(s) of the FPGA circuitry 1100 of FIG. 11 may be configured and/or structured to perform operations/functions corresponding to portion(s) of machine-readable instructions at the same and/or different times.

In some examples, some or all of the circuitry of FIGS. 10 and/or 11 may be instantiated, for example, in one or more threads executing concurrently and/or in series. For example, the microprocessor 1000 of FIG. 10 may execute machine-readable instructions in one or more threads executing concurrently and/or in series. In some examples, the FPGA circuitry 1100 of FIG. 11 may be configured and/or structured to carry out operations/functions concurrently and/or in series. Moreover, in some examples, some or all of the processor circuitry 912 of FIGS. 10 and/or 11 may be implemented within one or more virtual machines and/or virtual execution environments executing on the microprocessor 1000 of FIG. 10.

In some examples, the programmable circuitry 912 of FIG. 9 may be in one or more packages. For example, the microprocessor 1000 of FIG. 10 and/or the FPGA circuitry 1100 of FIG. 11 may be in one or more packages. In some examples, an XPU may be implemented by the programmable circuitry 912 of FIGS. 9, which may be in one or more packages. For example, the XPU may include a CPU (e.g., the microprocessor 1000 of FIG. 10, the CPU 1120 of FIG. 11, etc.) in one package, a DSP (e.g., the DSP 1122 of FIG. 11) in another package, a GPU in yet another package, and an FPGA (e.g., the FPGA circuitry 1100 of FIG. 11) in still yet another package.

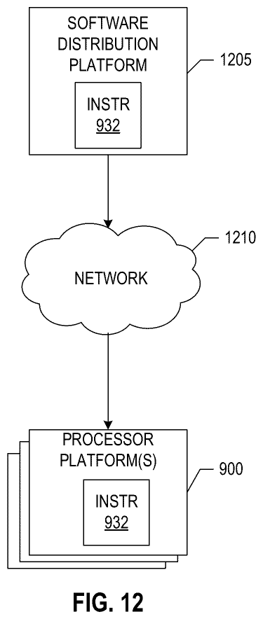

A block diagram illustrating an example software distribution platform 1205 to distribute software such as the example machine-readable instructions 932 of FIG. 9 to other hardware devices (e.g., hardware devices owned and/or operated by third parties from the owner and/or operator of the software distribution platform) is illustrated in FIG. 12. The example software distribution platform 1205 may be implemented by any computer server, data facility, cloud service, etc., capable of storing and transmitting software to other computing devices. The third parties may be customers of the entity owning and/or operating the software distribution platform 1205. For example, the entity that owns and/or operates the software distribution platform 1205 may be a developer, a seller, and/or a licensor of software such as the example machine-readable instructions 932 of FIG. 9. The third parties may be consumers, users, retailers, OEMs, etc., who purchase and/or license the software for use and/or re-sale and/or sub-licensing. In the illustrated example, the software distribution platform 1205 includes one or more servers and one or more storage devices. The storage devices store the machine-readable instructions 932, which may correspond to the example machine-readable instructions of FIG. 3, as described above. The one or more servers of the example software distribution platform 1205 are in communication with an example network 1210, which may correspond to the network 114 of FIG. 1. In some examples, the one or more servers are responsive to requests to transmit the software to a requesting party as part of a commercial transaction. Payment for the delivery, sale, and/or license of the software may be handled by the one or more servers of the software distribution platform and/or by a third-party payment entity. The servers enable purchasers and/or licensors to download the machine-readable instructions 932 from the software distribution platform 1205. For example, the software, which may correspond to the example machine-readable instructions of FIG. 3, may be downloaded to the example programmable circuitry platform 900 which is to execute the machine-readable instructions 932 to implement the processor circuitry 912. In some examples, one or more servers of the software distribution platform 1205 periodically offer, transmit, and/or force updates to the software (e.g., the example machine-readable instructions 932 of FIG. 9) to ensure improvements, patches, updates, etc., are distributed and applied to the software at the end user devices. Although referred to as software above, the distributed “software” could alternatively be firmware.

Example methods, apparatus, systems, and articles of manufacture to design and test electronics using artificial intelligence are disclosed herein. Further examples and combinations thereof include the following: Example 1 includes a non-transitory computer readable medium comprising instructions to cause at least one programmable circuit to use a first trained artificial intelligence (AI)-based model to generate verification code based on an input design, execute the verification code to generate a verifiability score for the input design, and based on the verifiability score, use a second trained AI-based model to adjust the input design.

Example 2 includes the non-transitory computer readable medium of example 1, wherein the input design is represented by at least one modality.

Example 3 includes the non-transitory computer readable medium of example 1, wherein the instructions cause one or more of the at least one programmable circuit to perform multimodal encoding on the input design when the input design is represented by two or more modalities.

Example 4 includes the non-transitory computer readable medium of example 1, wherein the instructions cause one or more of the at least one programmable circuit to input a prompt to the first trained AI-based model to generate the verification code.

Example 5 includes the non-transitory computer readable medium of example 1, wherein the verification code verify functionality of the input design.

Example 6 includes the non-transitory computer readable medium of example 1, wherein the verifiability score is a first verifiability store, the instructions to cause one or more of the at least one programmable circuit to execute the verification code to generate a second verifiability score of the adjusted input design.

Example 7 includes the non-transitory computer readable medium of example 1, wherein the verifiability score is a first verifiability store, the instructions to cause one or more of the at least one programmable circuit to output the adjusted input design as a final design when a second verifiability score of the adjusted input design satisfies a threshold.

Example 8 includes the non-transitory computer readable medium of example 1, wherein the instructions cause one or more of the at least one programmable circuit to train the first trained AI-based model by accessing a pre-trained foundation model, generating a generalized verification code model by fine tuning the pre-trained foundational model with tuning data corresponding to multiple code languages, and fine tuning the generalized verification code model with language specific tuning data.

Example 9 includes the non-transitory computer readable medium of example 1, wherein the instructions cause one or more of the at least one programmable circuit to train the second trained AI-based model by accessing a pre-trained foundation model, generating a generalized verification code model by fine tuning the pre-trained foundational model with tuning data corresponding to multiple code languages, the fine tuning of the pre-trained foundational model based on user feedback, and fine tuning the generalized verification code model with language specific tuning data.

Example 10 includes an apparatus comprising interface circuitry to obtain a design, computer readable instructions, and at least one programmable circuit to be programmable by the computer readable instruction to cause a first trained artificial intelligence (AI)-based model to generate verification code based on the design, generate a verifiability score for the design based on the verification code, and based on the verifiability score, cause a second trained AI-based model to update the design.

Example 11 includes the apparatus of example 10, wherein the design is represented by at least one modality.

Example 12 includes the apparatus of example 10, wherein one or more of the at least one programmable circuit is to perform multimodal encoding on the design if the design is represented by at least two modalities.

Example 13 includes the apparatus of example 10, wherein one or more of the at least one programmable circuit is to input a prompt to the first trained AI-based model to cause generation of the verification code.

Example 14 includes the apparatus of example 10, wherein the verification code is to seek errors in the design.

Example 15 includes the apparatus of example 10, wherein the verifiability score is a first verifiability store one or more of the at least one programmable circuit is to execute the verification code to generate a second verifiability score corresponding to the updated design.

Example 16 includes the apparatus of example 10, wherein the verifiability score is a first verifiability store, one or more of the at least one programmable circuit is to output the updated design as a final design when a second verifiability score of the updated design satisfies a threshold.

Example 17 includes the apparatus of example 10, wherein one or more of the at least one programmable circuit is to train the first trained AI-based model by accessing a pre-trained foundation model, generating a generalized verification code model by tuning the pre-trained foundational model with tuning data corresponding to multiple code languages, and generating the first trained AI-based model by tuning the generalized verification code model with language specific tuning data.

Example 18 includes the apparatus of example 10, wherein one or more of the at least one programmable circuit is to train the second trained AI-based model by accessing a pre-trained foundation model, generating a generalized verification code model by tuning the pre-trained foundational model with tuning data corresponding to multiple code languages, the tuning of the pre-trained foundational model based on user feedback, and generating the second trained AI-based model by tuning the generalized verification code model with language specific tuning data.

Example 19 includes an apparatus comprising interface circuitry to obtain a design, machine-readable instructions, and programmable circuitry to at least one of instantiate or execute the machine-readable instructions to cause a first artificial intelligence (AI)-based model to generate verification code based on the design, execute the verification code to generate a verifiability score corresponding to the design, and repeatedly cause a second AI-based model to adjust the design until the verifiability score satisfies a threshold.

Example 20 includes the apparatus of example 19, wherein the design is represented by at least one modality.

From the foregoing, it will be appreciated that example systems, apparatus, articles of manufacture, and methods have been disclosed to design and test electronics using artificial intelligence. Examples disclosed herein generate verifiability scores to test designs of electronic devices. Accordingly, examples disclosed herein improve the functionality and/or design of electronic devices by generating code that detects errors in the design. Additionally, examples disclosed herein adjust the design when the testing of the design identifies error(s). Thus, the disclosed systems, apparatus, articles of manufacture, and methods are accordingly directed to one or more improvement(s) in the operation of a machine such as a computer or other electronic and/or mechanical device.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

What is claimed is:

1. A non-transitory computer readable medium comprising instructions to cause at least one programmable circuit to:
use a first trained artificial intelligence (AI)-based model to generate verification code based on an input design;
execute the verification code to generate a verifiability score for the input design; and
based on the verifiability score, use a second trained AI-based model to adjust the input design.

2. The non-transitory computer readable medium of claim 1, wherein the input design is represented by at least one modality.

3. The non-transitory computer readable medium of claim 1, wherein the instructions cause one or more of the at least one programmable circuit to perform multimodal encoding on the input design when the input design is represented by two or more modalities.

4. The non-transitory computer readable medium of claim 1, wherein the instructions cause one or more of the at least one programmable circuit to input a prompt to the first trained AI-based model to generate the verification code.

5. The non-transitory computer readable medium of claim 1, wherein the verification code verify functionality of the input design.

6. The non-transitory computer readable medium of claim 1, wherein the verifiability score is a first verifiability store, the instructions to cause one or more of the at least one programmable circuit to execute the verification code to generate a second verifiability score of the adjusted input design.

7. The non-transitory computer readable medium of claim 1, wherein the verifiability score is a first verifiability store, the instructions to cause one or more of the at least one programmable circuit to output the adjusted input design as a final design when a second verifiability score of the adjusted input design satisfies a threshold.

8. The non-transitory computer readable medium of claim 1, wherein the instructions cause one or more of the at least one programmable circuit to train the first trained AI-based model by:
accessing a pre-trained foundation model;
generating a generalized verification code model by fine tuning the pre-trained foundational model with tuning data corresponding to multiple code languages; and
fine tuning the generalized verification code model with language specific tuning data.

9. The non-transitory computer readable medium of claim 1, wherein the instructions cause one or more of the at least one programmable circuit to train the second trained AI-based model by:
accessing a pre-trained foundation model;
generating a generalized verification code model by fine tuning the pre-trained foundational model with tuning data corresponding to multiple code languages, the fine tuning of the pre-trained foundational model based on user feedback; and
fine tuning the generalized verification code model with language specific tuning data.

10. An apparatus comprising:
interface circuitry to obtain a design;
computer readable instructions; and
at least one programmable circuit to be programmable by the computer readable instruction to:
cause a first trained artificial intelligence (AI)-based model to generate verification code based on the design;
generate a verifiability score for the design based on the verification code; and
based on the verifiability score, cause a second trained AI-based model to update the design.

11. The apparatus of claim 10, wherein the design is represented by at least one modality.

12. The apparatus of claim 10, wherein one or more of the at least one programmable circuit is to perform multimodal encoding on the design if the design is represented by at least two modalities.

13. The apparatus of claim 10, wherein one or more of the at least one programmable circuit is to input a prompt to the first trained AI-based model to cause generation of the verification code.

14. The apparatus of claim 10, wherein the verification code is to seek errors in the design.

15. The apparatus of claim 10, wherein the verifiability score is a first verifiability store one or more of the at least one programmable circuit is to execute the verification code to generate a second verifiability score corresponding to the updated design.

16. The apparatus of claim 10, wherein the verifiability score is a first verifiability store, one or more of the at least one programmable circuit is to output the updated design as a final design when a second verifiability score of the updated design satisfies a threshold.

17. The apparatus of claim 10, wherein one or more of the at least one programmable circuit is to train the first trained AI-based model by:
accessing a pre-trained foundation model;
generating a generalized verification code model by tuning the pre-trained foundational model with tuning data corresponding to multiple code languages; and
generating the first trained AI-based model by tuning the generalized verification code model with language specific tuning data.

18. The apparatus of claim 10, wherein one or more of the at least one programmable circuit is to train the second trained AI-based model by:
accessing a pre-trained foundation model;
generating a generalized verification code model by tuning the pre-trained foundational model with tuning data corresponding to multiple code languages, the tuning of the pre-trained foundational model based on user feedback; and
generating the second trained AI-based model by tuning the generalized verification code model with language specific tuning data.

19. An apparatus comprising:
interface circuitry to obtain a design;
machine-readable instructions; and
programmable circuitry to at least one of instantiate or execute the machine-readable instructions to:
cause a first artificial intelligence (AI)-based model to generate verification code based on the design;
execute the verification code to generate a verifiability score corresponding to the design; and
repeatedly cause a second AI-based model to adjust the design until the verifiability score satisfies a threshold.

20. The apparatus of claim 19, wherein the design is represented by at least one modality.
